(19) United States
(12) Patent Application Publication
(10) Pub. No.: US 2025/0385209 A1
(43) Pub. Date: Dec. 18, 2025

(54) BUMPLESS FAN-OUT WAFER-LEVEL INTEGRATED CIRCUIT PACKAGE INCLUDING MEMORY AND LOGIC

(71) Applicant: QUALCOMM Incorporated, San Diego, CA (US)

(72) Inventors: Jihong CHOI, San Diego, CA (US); Hyun LEE, San Diego, CA (US); Giridhar NALLAPATI, San Diego, CA (US); Mustafa BADAROGLU, San Diego, CA (US); Zhongze WANG, San Diego, CA (US); Woo Tag KANG, San Diego, CA (US); Periannan CHIDAMBARAM, San Diego, CA (US)

(21) Appl. No.: 18/743,067

(22) Filed: Jun. 13, 2024

(51) Int. Cl. H01L 23/00; H01L 21/56; H01L 23/498; H01L 25/18; H10B 80/00

(52) U.S. Cl. CPC H01L 24/16; H01L 21/56; H01L 24/13; H01L 24/17; H01L 24/81; H01L 25/18; H10B 80/00; H01L 23/49833; H01L 24/32; H01L 24/73; H01L 2224/13147; H01L 2224/16225; H01L 2224/1703; H01L 2224/32145; H01L 2224/73253; H01L 2224/81191; H01L 2225/06517; H01L 2225/06548; H01L 2225/06562; H01L 2924/1431; H01L 2924/1436

(57) ABSTRACT

An integrated circuit package is provided including both an upper redistribution layer and a lower redistribution layer. A first stack of memory dies couples to the upper redistribution layer either through metal posts or through vertical wire bonds. Similarly, a second stack of memory dies couples to the lower redistribution layer either through metal posts or through vertical wire bonds. A logic die also couples to the lower redistribution layer through a plurality of interconnects.

### TECHNICAL FIELD

The present application relates generally to integrated circuit packaging, and more specifically, to a bumpless fan-out wafer-level integrated circuit package including memory and logic.

### BACKGROUND

The combination of edge computing and artificial intelligence (AI) applications has led to the development of edge AI devices such as sensors in automotive applications, edge-AI-enabled cellular telephones, or Internet of Things (IOT) devices. Prior to the development of edge AI, the engine of an edge computing device (e.g., a microcontroller unit) would typically need to upload data to the cloud for AI processing. But with machine learning built into an edge AI device, the AI processing remains on the device so as to significantly decrease latency, reduce power consumption, and increase data security. In an edge AI device, a data connection from a logic circuit such as the microcontroller unit to its associated memories such as dynamic random-access memories (DRAMs) should have a relatively large bandwidth to accommodate the large amounts of data that travels back and forth from the logic circuit to the memories.

The logic circuit and the DRAMs are typically integrated into separate semiconductor dies. The resulting packaging of the logic die and the DRAM dies into a single integrated circuit package faces significant challenges in maintaining a small form factor and satisfying the relatively large bandwidth needed for the data flow between the logic die and the DRAM dies.

### SUMMARY

In accordance with an aspect of the disclosure, an integrated circuit package is provided that includes: an upper redistribution layer; a first stack of memory dies; a first plurality of metal pillars coupled between the first stack of memory dies and the upper redistribution layer; a lower redistribution layer; a logic die; a plurality of interconnects coupled between the logic die and the lower redistribution layer; a second stack of memory dies; and a second plurality of metal pillars coupled between the second stack of memory dies and the lower redistribution layer.

In accordance with another aspect of the disclosure, a method of manufacturing an integrated circuit package is provided that includes: bonding a back side of a first memory die to a carrier substrate; bonding a back side of at least one second memory die to an active surface of the first memory die so as to leave a lateral portion of the first memory die uncovered by the at least one second memory die; depositing metal pillars on the lateral portion of first memory die; encapsulating the first memory die and the at least one second memory die with a first mold compound; depositing an upper redistribution layer on a surface of the first mold compound, the upper redistribution layer having a surface facing the surface of the first mold compound and having an opposing surface facing away from the surface of the first mold compound; and bonding a back side of a logic die to the opposing surface.

Finally, in accordance with another aspect of the disclosure, an integrated circuit package is provided that includes: an upper redistribution layer; a first stack of memory dies; a first plurality of vertical wire bonds coupled between the first stack of memory dies and the upper redistribution layer; a lower redistribution layer; a logic die; a plurality of interconnects coupled between the logic die and the lower redistribution layer; a second stack of memory dies; and a third plurality of vertical wire bonds coupled between the second stack and the lower redistribution layer.

These and other advantageous features may be better appreciated through the following detailed description.

### BRIEF DESCRIPTION OF THE DRAWINGS

FIG. 1 illustrates a bumpless fan-out wafer-level (FoWL) integrated circuit package including a logic die and a plurality of memory dies in which the memory dies are coupled to corresponding redistribution layers through metal pillars in accordance with an aspect of the disclosure.

FIG. 2 illustrates a bumpless fan-out wafer-level (FoWL) integrated circuit package including a logic die and a plurality of memory dies in which the memory dies are coupled to corresponding redistribution layers through vertical wire bonds in accordance with an aspect of the disclosure.

FIG. 3A illustrates an initial stage in the manufacture of the integrated circuit package of FIG. 1 including the bonding of the back side of DRAM dies to a carrier substrate in accordance with an aspect of the disclosure.

FIG. 3B illustrates the deposition of metal pillars onto the active surface of the DRAM dies of FIG. 3A in accordance with an aspect of the disclosure.

FIG. 3C illustrates the bonding of the back side of additional DRAM dies to the active surface of the DRAM dies of FIG. 3B in accordance with an aspect of the disclosure.

FIG. 3D illustrates the encapsulation of the DRAM dies and metal pillars of FIG. 3C with mold compound followed by a grinding and polishing of the mold compound surface in accordance with an aspect of the disclosure.

FIG. 3E illustrates the deposition of the upper redistribution layer on the polished mold surface of FIG. 3D in accordance with an aspect of the disclosure.

FIG. 3F illustrates the formation of through-mold vias and the bonding of the back side of a lower DRAM die onto the upper redistribution layer of FIG. 3E as well as the deposition of metal pillars on the active surface of the lower DRAM die in accordance with an aspect of the disclosure.

FIG. 3G illustrates the bonding of the back side of the logic die onto the lower redistribution layer and also the bonding of an additional lower DRAM die onto the active surface of the lower DRAM die of FIG. 3F in accordance with an aspect of the disclosure.

FIG. 3H illustrates the encapsulation of the logic die, the through-mold vias, and the lower DRAM dies of FIG. 3G with mold compound, and also the grinding and polishing of the mold compound surface in accordance with an aspect of the disclosure.

FIG. 3I illustrates the deposition of the lower redistribution layer onto the polished mold surface of FIG. 3H as well as the formation of bumps onto the lower redistribution layer in accordance with an aspect of the disclosure.

FIG. 4 is a flowchart for an example method of manufacturing an integrated circuit package including a logic die and memory dies in accordance with an aspect of the disclosure.

FIG. 5 illustrates some example electronic systems including an integrated circuit package in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

In a three-dimensional (3D) integrated circuit package of memory dies, the memory dies are typically stacked using a die-to-wafer (DtW) process and coupled together using a via-first process. The resulting process is costly. To lower costs, a 2.5-dimensional (2.5D) process may be used in which a stack of memory dies couple through a ball grid array to an interposer and from the interposer to the logic die. The bump pitch (required separation between adjacent bumps) limits the bandwidth for the data flow to the memory dies. A stacked integrated circuit package is disclosed herein including both an upper redistribution layer and a lower redistribution layer that advantageously offers significantly improved bandwidth over 2.5D approaches while offering lower cost as compared to 3D approaches. Some example implementations will now be discussed in more detail.

The logic die in an AI edge device will typically interface with multiple memory dies such as DRAM dies due to the relatively large amount of data needed for AI applications. The following discussion will be directed to the use of DRAM dies in the vertically stacked integrated circuit package to provide this increased memory capacity, but it will be appreciated that other types of random-access memory (RAM) dies such as magnetic RAM may be used in alternative implementations. To maintain a small footprint (package size), the DRAM dies disclosed herein are stacked above both the upper redistribution layer and the lower redistribution layer. The stacked DRAM dies couple to their respective redistribution layer through metal pillars or vertical wire bonds. In addition, the logic die couples to one of the redistribution layers through a plurality of interconnects such as metal pillars or micro bumps. The following discussion is directed to implementations in which the logic die couples to the lower redistribution layer but it will be appreciated that the logic die may instead be coupled to the upper redistribution layer in alternative implementations. The logic die thus has its active surface coupled to the lower redistribution layer through its plurality of interconnects.

Each of the DRAM dies is arranged in its stack to have its active surface facing the corresponding redistribution layer. A bottom-most DRAM die in a stack will thus have its entire active surface facing the corresponding redistribution layer. The stacks are staggered so that each successive DRAM die in a stack has a lateral portion of its active surface that is not shadowed or blocked by a preceding DRAM of the stack. For example, a DRAM die immediately above the bottom-most DRAM die in a stack may be laterally displaced in a first direction with respect to the bottom-most DRAM die so that a lateral portion of the active surface of the displaced DRAM die faces the corresponding redistribution layer without any shadowing by the bottom-most DRAM die. This lateral displacement from a lower DRAM die to an upper DRAM die continues in the first direction so that each DRAM die in the stack has an uncovered lateral portion of its active surface facing the corresponding redistribution layer. In this fashion, metal pillars (or vertical wire bonds) may couple vertically from conductive pads on this uncovered lateral portion to conductive pads on the respective redistribution layer. A plurality of through-mold vias couple between the upper and lower redistribution layers to conduct the signaling between the redistribution layers.

As compared to the use of bumps in a traditional 2.5D integrated circuit package, the use of metal pillars or vertical wire bonds to form the DRAM die interconnects provides a smaller pitch between adjacent ones of the interconnects. With this reduced pitch, more interconnects may be deposited onto the available DRAM die space to provide an increased data bandwidth or transmission speed as compared to a traditional 2.5D integrated circuit package. For example, in some implementations the pitch between adjacent bumps is greater than 60 microns whereas the pitch between adjacent metal pillars or vertical wire bonds may be less than 30 microns.

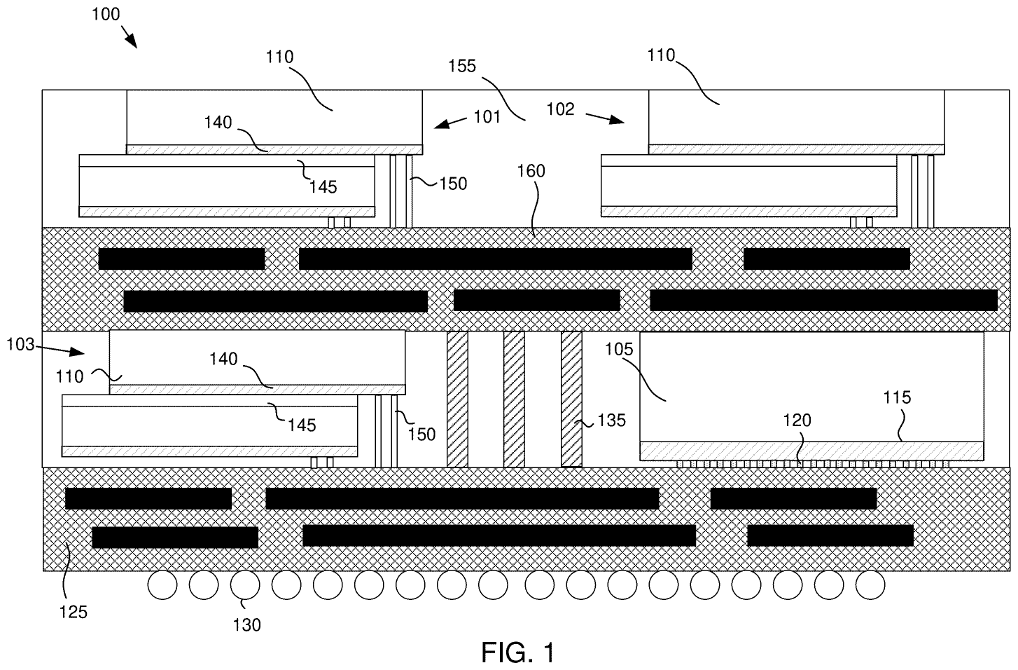

An example vertically stacked integrated circuit package 100 including a plurality of stacks of DRAM dies 110 shown in FIG. 1. The DRAM dies 110 are stacked above an upper redistribution layer 160 and also a lower redistribution layer 125. The number of stacks above a particular one of the redistribution layers depends upon a location of a logic die 105 in the package 100. Should a plurality of interconnects such as a plurality of metal pillars 120 couple between conductive pads (not illustrated) on an active surface 115 of the logic die 105 and conductive pads (not illustrated) on the lower redistribution layer 125, then a plurality of stacks such as an upper stack 101 and an upper stack 102 of DRAM dies couple through metal pillars 150 (or through vertical wire bonds) to the upper redistribution layer 160. The coupling of the logic die 105 to the lower redistribution layer 125 would then leave room for only an at least one stack such as a lower stack 103 of DRAM dies to couple to the lower redistribution layer 125. Should instead the logic die 105 couple to the upper redistribution layer 160 through a corresponding plurality of interconnects, then it would be the lower redistribution layer 125 receiving a plurality of stacks of DRAM dies. Either of the upper stacks 101 and 102 may be denoted as a first stack herein. Similarly, the lower stack 103 is also denoted herein as a second stack.

Each DRAM die 110 is arranged in its stack to have its active surface 140 including both a front-end-of-line layer (not illustrated) and a back-end-of-line layer (not illustrated) facing the corresponding redistribution layer. Within each stack, the DRAM dies 110 are bonded together through corresponding bonding layers 145. A plurality of through-mold vias 135 couple between respective conductive pads (not illustrated) on a lower surface of the upper redistribution layer 160 and an upper surface of the lower redistribution layer 125. A mold compound 155 such as epoxy encapsulates the DRAM dies 110 and their metal pillars 150, the logic die 105 and its metal pillars 120, and the through-mold vias 135. Although the same mold compound may be used, the mold compound 155 encapsulating the upper stacks 101 and 102 may also be denoted herein as a first mold compound whereas the mold compound 155 encapsulating the lower stack 103 may be denoted herein as a second mold compound.

The upper redistribution layer 160 and the lower redistribution layer 125 may each be formed using a suitable dielectric polymer such as polyimide that is photolithographically patterned in either a positive or negative fashion. A conductive metal such as copper or titanium/copper may then be sputtered or electroplated onto the patterned dielectric polymer to form the desired electrical connections in the redistribution layers 160 and 125. The metal and dielectric polymer may be layered so that multiple patterned metal layers are present in the redistribution layers 160 and 125. For example, each of the redistribution layers may include at least two patterned metal layers in some implementations.

Each stack 101, 102, and 103 of DRAM dies 110 is staggered in one lateral direction to expose a lateral portion of the active surface 140 of each overlying DRAM die 110. For example, the bottom-most DRAM die 110 in the stack 102 is displaced to the left with respect to the DRAM die 110 immediately above it. Metal pillars 150 may thus extend vertically from conductive pads (not illustrated) in the resulting exposed lateral portion of the active surface 120 of this overlying DRAM die 110 to couple to corresponding conductive pads (not illustrated) on an upper surface of the upper redistribution layer 160. Stacks 101, 102, and 103 have just two DRAM dies 110 but it will be appreciated that more than two DRAM dies 110 may be included in alternative stack implementations. Regardless of whether there is only two or more than two DRAM dies 110 in each stack, the lateral displacement of successive ones of the DRAM dies in the stack extends in the same direction throughout the stack. In this fashion, each exposed lateral portion of successively higher ones of the DRAM dies 110 in a stack is not shadowed by lower DRAM dies 110 in the stack.

Consider a data read such as from one of the DRAM dies 110 in the upper stack 101 or 102. The data conducts from the active surface 140 of the respective DRAM die 110 and through the corresponding metal pillars 150 to the upper redistribution layer 160. The data then conducts through metal leads in the redistribution layer 160 to corresponding ones of the through-mold vias 135. From the through-mold vias 135, the data would propagate through metal leads in the lower redistribution layer 125 to corresponding metal pillars 120 to be received by the active layer 115 in the logic die 105. A write operation would proceed in the reverse of the read operation. The data propagation is thus advantageously bumpless in that is not bottlenecked by the bandwidth-reducing effect of having to pass through bumps such as would occur in a traditional 2.5D architecture and instead may propagate with a relatively high data rate. Moreover, the resulting package 100 is relatively low cost and readily manufactured using a fan-out wafer-level process as will be explained further herein.

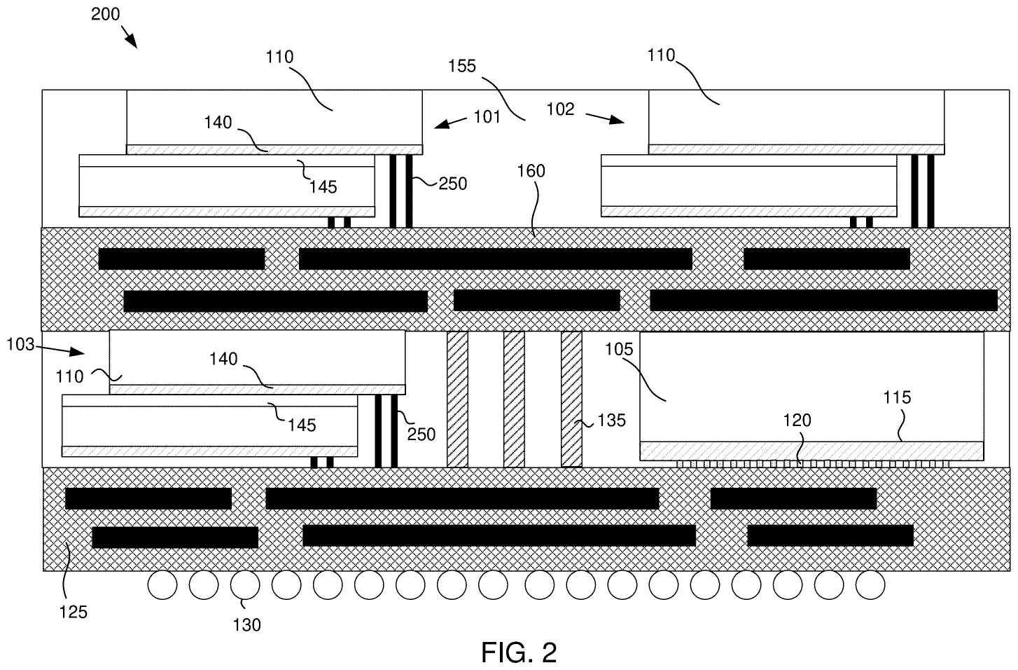

In an alternative implementation as shown in FIG. 2 for a vertically stacked integrated circuit package 200, the metal pillars 150 are replaced with vertical wire bonds 250. The remainder of the integrated circuit package 200 is as discussed for the integrated circuit package 100.

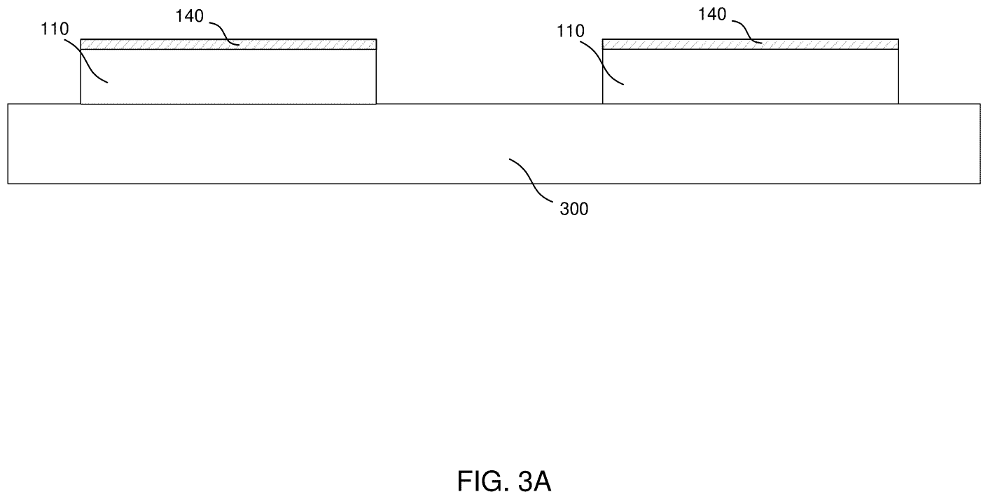

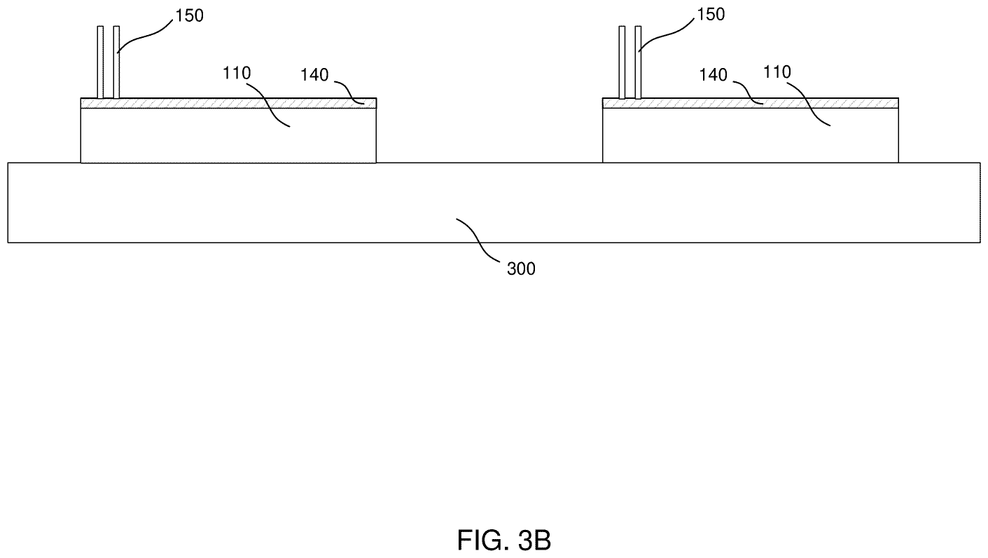

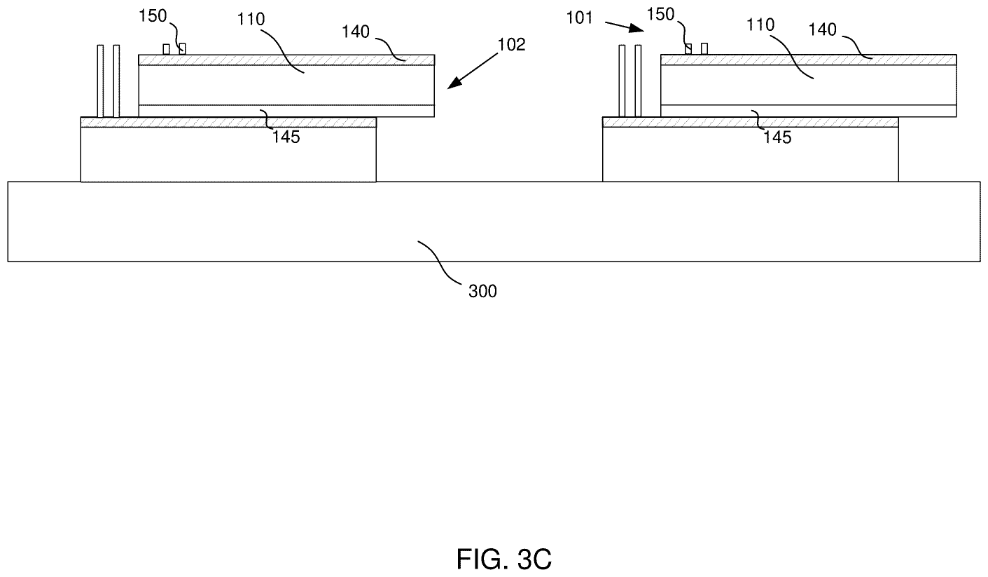

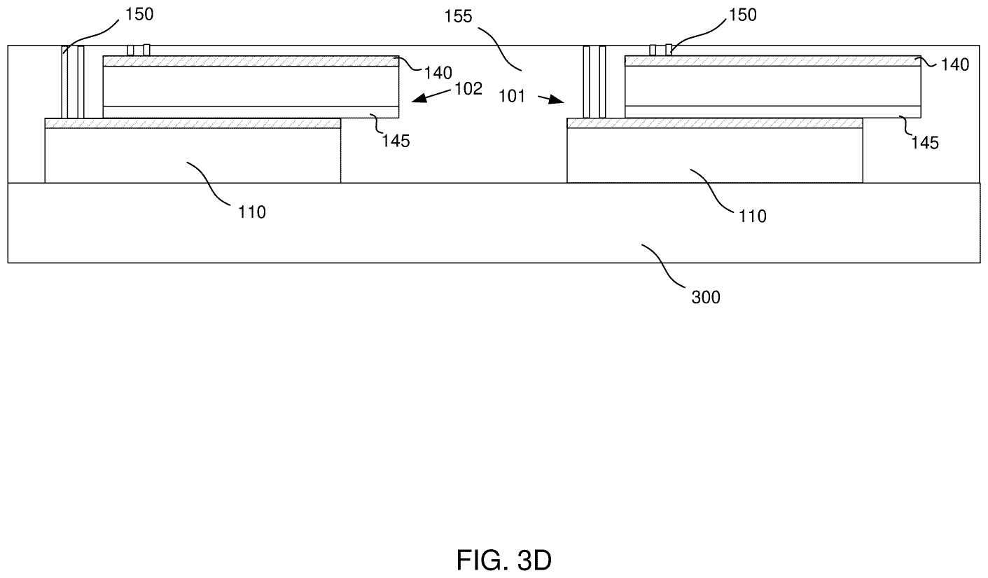

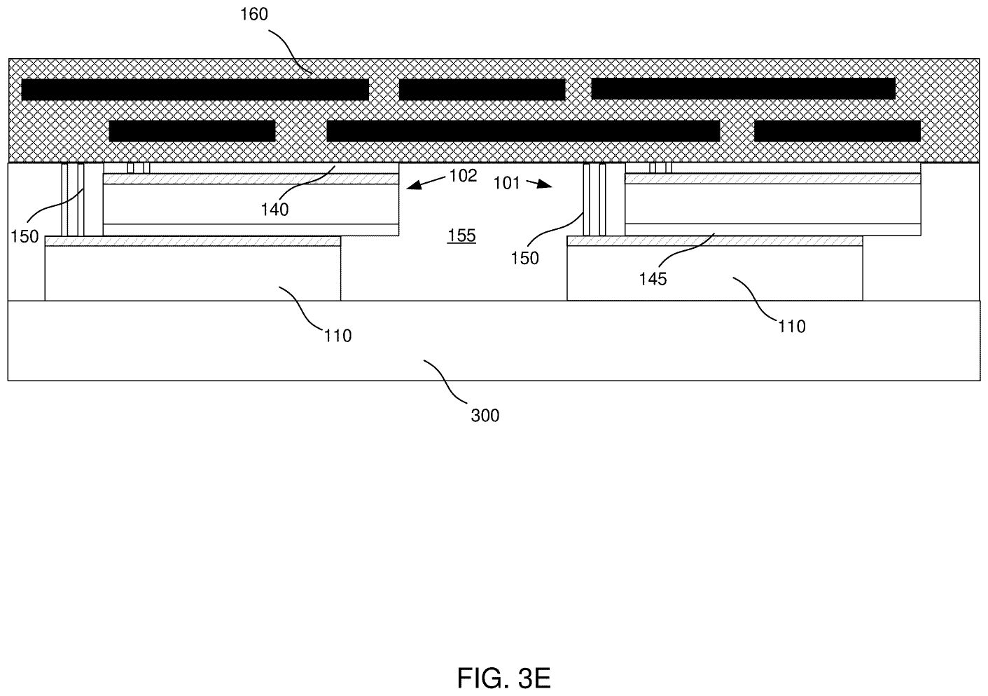

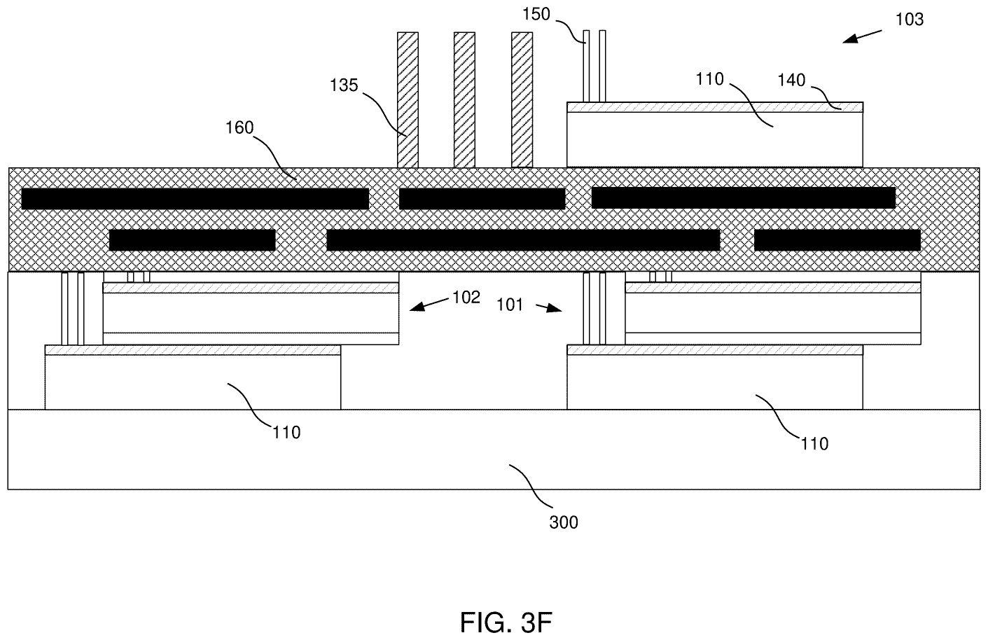

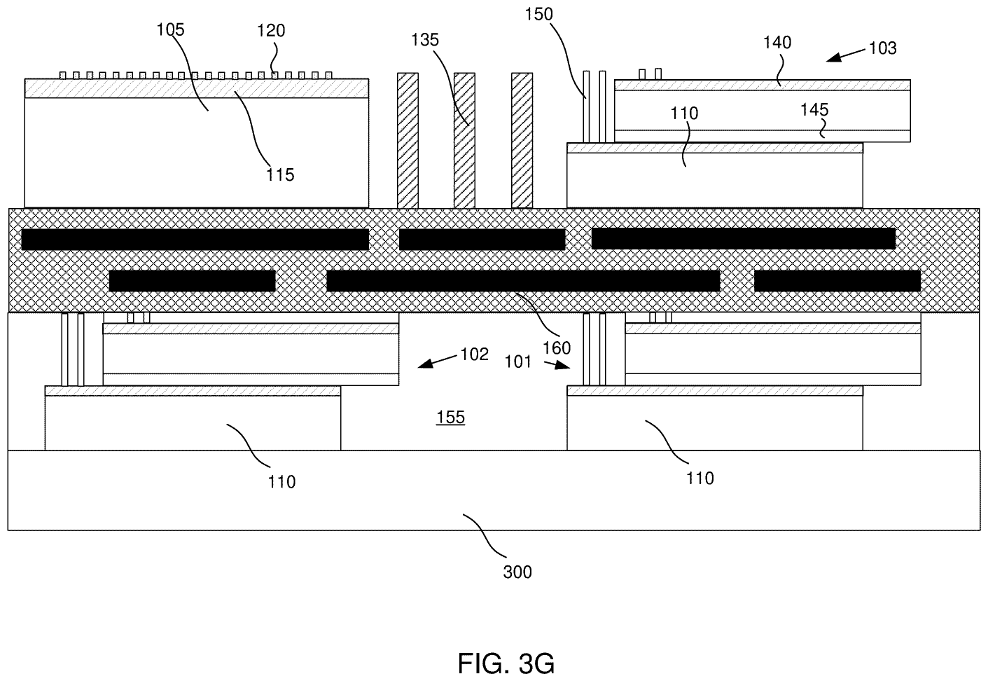

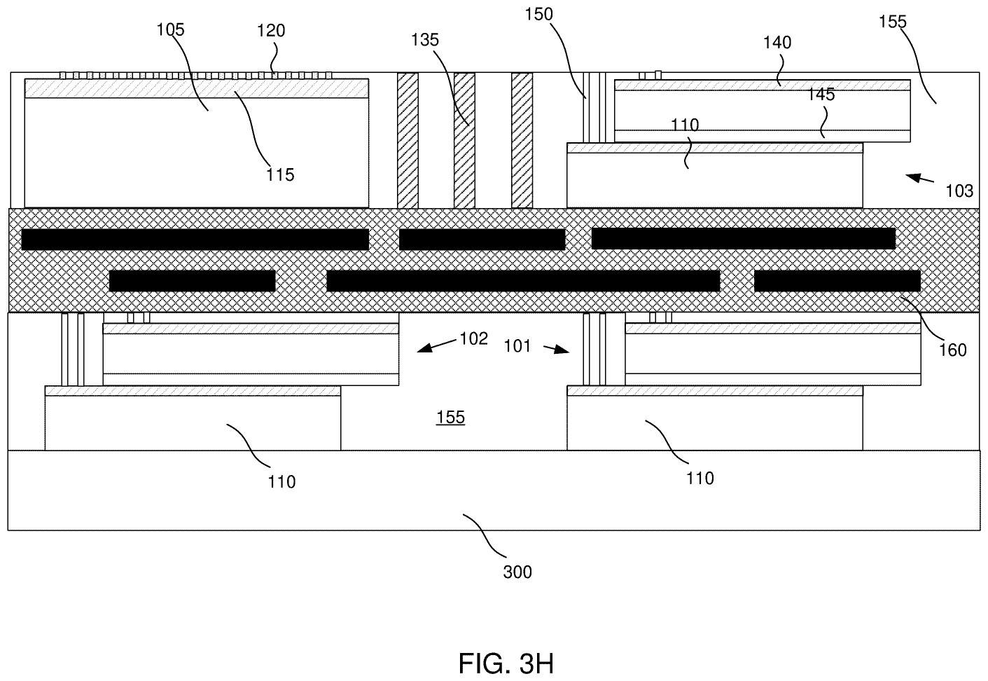

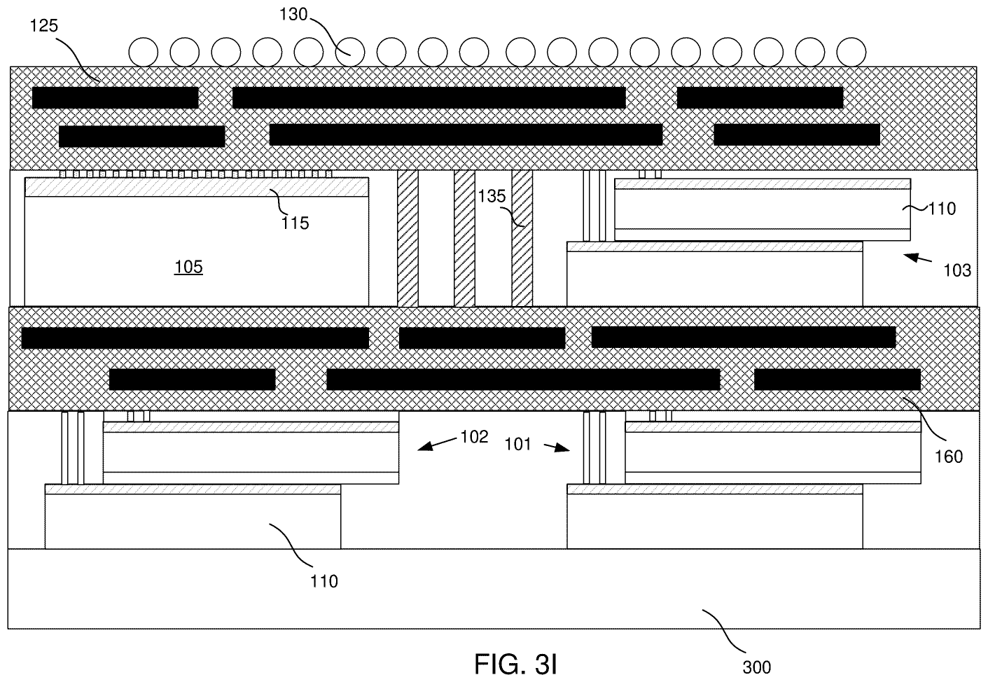

A process for the manufacture of the vertically stacked integrated circuit package 100 (or 200) will now be discussed. The process begins with the bonding of the back side of the upper-most DRAM dies 110 from the upper stacks 101 and 102 through corresponding bonding layers (not illustrated) to a carrier substrate 300 as shown in FIG. 3A. The carrier substrate 300 may be wafer sized such that the resulting fabrication is a fan-out wafer-level co-packaging (FoWLcP) process. The deposition of metal pillars 150 (e.g., copper, gold, or silver metal pillars or posts) onto conductive pads (not illustrated) on the active surface of the DRAM dies 110 of FIG. 3A is shown in FIG. 3B. To form the metal pillars 150, a seed layer of metal such as copper may be deposited over what will become the exposed lateral portion of the active surface 140 followed by the deposition of a photoresist layer. The photoresist layer is then patterned with vias so that the vias may be electroplated with metal (e.g., copper) to form metal pillars 150 (e.g., copper posts) over the corresponding conductive pads on the active surface 140. The photoresist layer is then removed followed by a light etching to remove the remaining seed layer to complete the metal pillars 150. Alternatively, a suitable wire bonding machine may bond vertical wire bonds 250 (in lieu of the metal pillars 150) to the corresponding conductive pads (not illustrated) on the exposed lateral portions of the active surfaces 140 of the DRAM dies 110.

As shown in FIG. 3C, what will become the bottom-most DRAM dies 110 are then stacked onto the DRAM dies 110 from FIG. 3B in a staggered fashion and secured through corresponding bonding layers 145 to form the upper stacks 101 and 102. In addition, the metal pillars 150 are deposited on onto the active surface of these added DRAM dies 110 analogously as discussed for FIG. 3B (alternatively, vertical wire bonds 250 may be formed in lieu of the metal pillars 150). The upper stacks 101 and 102 as well as the corresponding metal pillars 150 are then encapsulated with mold compound 155 as shown in FIG. 3D. The mold compound surface is then ground and polished so that the upper redistribution layer 160 may be deposited as shown in FIG. 3E. This deposition may be wafer-sized as discussed analogously for the carrier substrate 300. The fan-out of the resulting fan-out wafer-scale process occurs through the upper redistribution layer 160 (and also through the lower redistribution layer 125). With the upper redistribution layer 160 deposited, the through-mold vias 135 may be deposited onto conductive pads (not illustrated) on what will become the lower surface of the upper redistribution layer 160 as shown in FIG. 3F. The formation of the through-mold vias 135 may be performed using photolithography and electroplating or vapor deposition analogously as discussed for the formation of the metal pillars 150. In addition, the back side of what will become the upper-most DRAM die 110 in the lower stack 103 may be bonded to the upper redistribution layer 160. Finally, metal pillars 150 (or vertical wire bonds 250) are deposited on conductive pads (not illustrated) on what will become the exposed lateral portion of the active surface 140 of this upper-most DRAM die 110.

As shown in FIG. 3G, a back side of the logic die 105 is bonded through a corresponding bonding layer (not illustrated) to what will become the lower surface of the upper redistribution layer 160. In addition, what will become the lower-most or bottom DRAM die 110 in the lower stack 103 is attached through a bonding layer 145 as also shown in FIG. 3G. Metal pillars 150 (or vertical wire bonds 250) are also deposited on the active surface 140 of this bottom DRAM die 110. Finally, metal pillars 120 are deposited on the active surface 115 of the logic die 105. In alternative implementations, the logic die 105 may already be populated with metal pillars 120 prior to the bonding of the logic die to the upper redistribution layer 160. In such implementations, the metal pillars 120 may also already be encapsulated with mold compound. In FIG. 3H, the through-mold vias 135, the lower stack 103, and the logic die 105 are encapsulated with mold compound 155. The resulting mold compound 155 is then ground and polished so that the lower redistribution layer 125 may be deposited over the polished mold compound surface as shown in FIG. 2I. As discussed for the upper redistribution layer 160, the deposition of the lower redistribution layer 125 may be wafer-sized. In addition, bumps 130 (e.g., solder bumps such as a ball grid array) may then be deposited on what will become the lower surface of the lower redistribution layer 125. The carrier substrate 300 is removed and the package 100 may then be singulated to complete its manufacture.

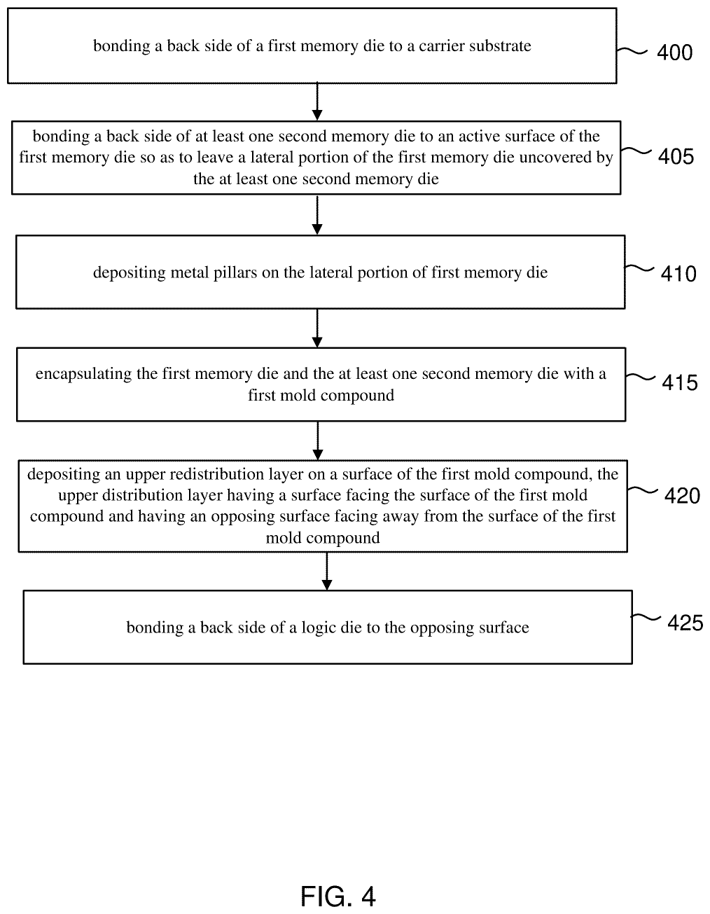

A method of manufacture for the integrated package 100 will now be summarized with respect to the flowchart of FIG. 4. The method includes an act 400 of bonding a back side of a first memory die to a carrier substrate. The bonding of the top-most DRAM die 110 in either of the upper stacks 101 or 102 to the carrier substrate as discussed with respect to FIG. 3A is an example of act 400. The method also includes an act 405 of bonding a back side of an at least one second memory die to an active surface of the first memory die so as to leave a lateral portion of the first memory die uncovered by the at least one second memory die. The bonding of the bottom DRAM die 110 in either of the upper stacks 101 or 102 as discussed with respect to FIG. 3C is an example of act 405. The method also includes an act 410 of depositing metal pillars on the lateral portion of first memory die. The deposition of the metal pillars 150 on the top-most DRAM die 110 in either of the upper stacks 101 or 102 as discussed with respect to FIG. 3B is an example of act 410. In addition, the method includes an act 415 of encapsulating the first memory die and the at least one second memory die with a first mold compound. The encapsulation of either of the upper stacks 101 or 102 with mold compound 155 as discussed with respect to FIG. 3D is an example of act 415. The method also includes an act 420 of depositing an upper redistribution layer on a surface of the first mold compound, the upper distribution layer having a surface facing the surface of the first mold compound and having an opposing surface facing away from the surface of the first mold compound. The deposition of the upper redistribution layer 160 as discussed with respect to FIG. 3E is an example of act 420. Finally, the method includes an act 425 of bonding a back side of a logic die to the opposing surface. The bonding of the logic die 105 to the upper redistribution layer 160 as discussed with respect to FIG. 3F is an example of act 425.

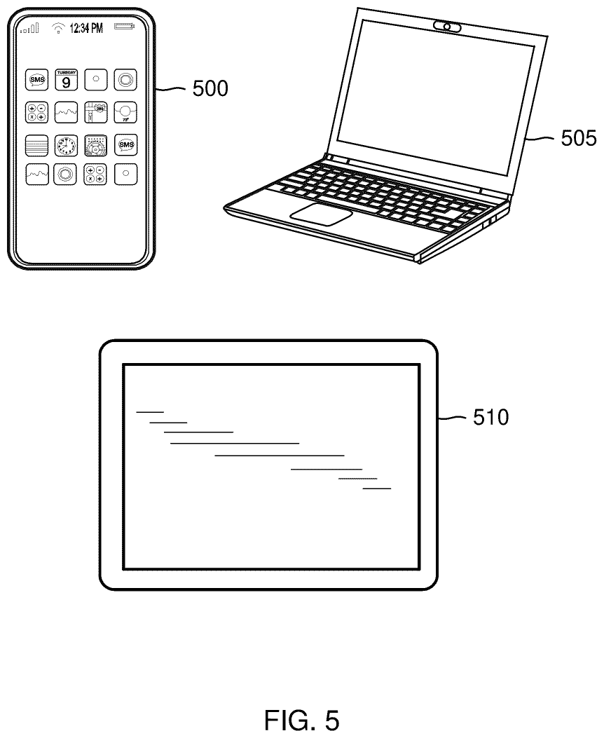

A vertically stacked integrated circuit package including a logic die and a plurality of memory dies as disclosed herein may be incorporated in a wide variety of electronic systems. For example, as shown in FIG. 5, a cellular telephone 500, a laptop computer 505, and a tablet 510 may all include an integrated circuit package in accordance with the disclosure. Other exemplary edge-AI-enabled electronic systems such as automotive sensors, video doorbells, and so on may also be configured with an integrated circuit package constructed in accordance with the disclosure.

Some example implementations are described by the following numbered clauses:

Clause 1. An integrated circuit package comprising:
an upper redistribution layer;
a first stack of memory dies;
a first plurality of metal pillars coupled between the first stack of memory dies and the upper redistribution layer;
a lower redistribution layer;
a logic die;
a plurality of interconnects coupled between the logic die and the lower redistribution layer;
a second stack of memory dies; and
a third plurality of metal pillars coupled between the second stack of memory dies and the lower redistribution layer.

Clause 2. The integrated circuit package of clause 1, further comprising:
a plurality of through-mold vias coupled between the upper redistribution layer and the lower redistribution layer.

Clause 3. The integrated circuit package of any of clauses 1-2, further comprising:
a third stack of memory dies; and
a third plurality of metal pillars coupled between the third stack of memory dies and the upper redistribution layer.

Clause 4. The integrated circuit package of any of clauses 1-3, wherein the first stack of memory dies comprises a stack of dynamic random-access memory dies, and wherein each successive one of the dynamic random-access memory dies in the first stack is displaced laterally in a first direction from a preceding one of the dynamic random-access memory dies in the first stack.

Clause 5. The integrated circuit package of any of clauses 1-4, wherein the first plurality of metal pillars comprises a plurality of copper posts.

Clause 6. The integrated circuit package of any of clauses 1-4, wherein the plurality of interconnects comprises a plurality of metal pillars.

Clause 7. The integrated circuit package of any of clauses 1-6, wherein the first stack of memory dies, the first plurality of metal pillars, the second stack of memory dies, the second plurality of metal pillars, the logic die, and the plurality of interconnects are all encapsulated in mold compound.

Clause 8. The integrated circuit package of any of clauses 1-7, wherein the upper redistribution layer and the lower redistribution layer each includes at least two metal layers.

Clause 9. A method of manufacturing an integrated circuit package, comprising:
bonding a back side of a first memory die to a carrier substrate;
bonding a back side of at least one second memory die to an active surface of the first memory die so as to leave a lateral portion of the first memory die uncovered by the at least one second memory die;
depositing metal pillars on the lateral portion of first memory die;
encapsulating the first memory die and the at least one second memory die with a first mold compound;
depositing an upper redistribution layer on a surface of the first mold compound, the upper redistribution layer having a surface facing the surface of the first mold compound and having an opposing surface facing away from the surface of the first mold compound; and
bonding a back side of a logic die to the opposing surface.

Clause 10. The method of clause 9, wherein depositing metal pillars on the lateral portion of the first memory die comprises electroplating copper pillars on the lateral portion of the first memory die.

Clause 11. The method of any of clauses 9-10, further comprising:
bonding a back side of a third memory die to the opposing surface;
bonding a back side of at least one fourth memory die to an active surface of the third memory die so as to leave a lateral portion of the third memory die uncovered by the at least one fourth memory die;
depositing metal pillars on the lateral portion of first memory die;
forming a second stack of memory dies on the opposing surface, wherein each successive memory die in the second stack is laterally displaced with respect to a preceding memory die in the second stack such that each successive memory die in the second stack has an exposed lateral portion of its active surface; and
depositing metal pillars on each exposed lateral portion of the second stack.

Clause 12. The method of clause 11, further comprising:
encapsulating the logic die and the second stack with a second mold compound; and
depositing a lower redistribution layer on a surface of the second mold compound.

Clause 13. The method of any of clauses 9-12, wherein the carrier substrate is wafer-sized, and wherein depositing the upper redistribution layer comprises depositing a wafer-sized upper redistribution layer.

Clause 14. The method of clause 9, further comprising:
bonding a back side of a third memory die to the carrier substrate;
bonding a back side of at least one fourth memory die to an active surface of the third memory die so as to leave a lateral portion of the third memory die uncovered by the at least one fourth memory die; and
depositing metal pillars on the lateral portion of third memory die, wherein encapsulating the first memory die and the at least one second memory die with the first mold compound further comprises encapsulating the third memory die and the at least one fourth memory die with the first mold compound.

Clause 15. An integrated circuit package comprising:
an upper redistribution layer;
a first stack of memory dies;
a first plurality of vertical wire bonds coupled between the first stack of memory dies and the upper redistribution layer;
a lower redistribution layer;
a logic die;
a plurality of interconnects coupled between the logic die and the lower redistribution layer;
a second stack of memory dies; and
a third plurality of vertical wire bonds coupled between the second stack and the lower redistribution layer.

Clause 16. The integrated circuit package of clause 15, further comprising:
a plurality of through-mold vias coupled between the upper redistribution layer and the lower redistribution layer.

Clause 17. The integrated circuit package of any of clauses 15-16, further comprising:
a third stack of memory dies; and
a third plurality of vertical wire bonds coupled between the third stack of memory dies and the upper redistribution layer.

Clause 18. The integrated circuit package of any of clauses 15-17, wherein the first stack of memory dies comprises a stack of dynamic random-access memory dies, and wherein each successive one of the dynamic random-access memory dies in the first stack is displaced laterally in a first direction from a preceding one of the dynamic random-access memory dies in the first stack.

Clause 19. The integrated circuit package of any of clauses 15-18, wherein the plurality of interconnects comprises a plurality of metal pillars.

Clause 20. The integrated circuit package of any of clauses 15-18, wherein the plurality of interconnects comprises a plurality of micro bumps.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. An integrated circuit package comprising:
an upper redistribution layer;
a first stack of memory dies;
a first plurality of metal pillars coupled between the first stack of memory dies and the upper redistribution layer;
a lower redistribution layer;
a logic die;
a plurality of interconnects coupled between the logic die and the lower redistribution layer;
a second stack of memory dies; and
a second plurality of metal pillars coupled between the second stack of memory dies and the lower redistribution layer.

2. The integrated circuit package of claim 1, further comprising:
a plurality of through-mold vias coupled between the upper redistribution layer and the lower redistribution layer.

3. The integrated circuit package of claim 1, further comprising:
a third stack of memory dies; and
a third plurality of metal pillars coupled between the third stack of memory dies and the upper redistribution layer.

4. The integrated circuit package of claim 1, wherein the first stack of memory dies comprises a stack of dynamic random-access memory dies, and wherein each successive one of the dynamic random-access memory dies in the first stack is displaced laterally in a first direction from a preceding one of the dynamic random-access memory dies in the first stack.

5. The integrated circuit package of claim 1, wherein the wherein the first plurality of metal pillars comprises a plurality of copper posts.

6. The integrated circuit package of claim 1, wherein the plurality of interconnects comprises a plurality of metal pillars.

7. The integrated circuit package of claim 1, wherein the first stack of memory dies, the first plurality of metal pillars, the second stack of memory dies, the second plurality of metal pillars, the logic die, and the plurality of interconnects are all encapsulated in mold compound.

8. The integrated circuit package of claim 1, wherein the integrated circuit package is incorporated into a cellular telephone.

9. A method of manufacturing an integrated circuit package, comprising:
bonding a back side of a first memory die to a carrier substrate;
bonding a back side of at least one second memory die to an active surface of the first memory die so as to leave a lateral portion of the first memory die uncovered by the at least one second memory die;
depositing metal pillars on the lateral portion of first memory die;
encapsulating the first memory die and the at least one second memory die with a first mold compound;
depositing an upper redistribution layer on a surface of the first mold compound, the upper redistribution layer having a surface facing the surface of the first mold compound and having an opposing surface facing away from the surface of the first mold compound; and
bonding a back side of a logic die to the opposing surface.

10. The method of claim 9, wherein depositing metal pillars on the lateral portion of the first memory die comprises electroplating copper pillars on the lateral portion of the first memory die.

11. The method of claim 9, further comprising:
bonding a back side of a third memory die to the opposing surface;
bonding a back side of at least one fourth memory die to an active surface of the third memory die so as to leave a lateral portion of the third memory die uncovered by the at least one fourth memory die;
depositing metal pillars on the lateral portion of first memory die;
forming a second stack of memory dies on the opposing surface, wherein each successive memory die in the second stack is laterally displaced with respect to a preceding memory die in the second stack such that each successive memory die in the second stack has an exposed lateral portion of its active surface; and
depositing metal pillars on each exposed lateral portion of the second stack.

12. The method of claim 11, further comprising:
encapsulating the logic die and the second stack with a second mold compound; and
depositing a lower redistribution layer on a surface of the second mold compound.

13. The method of claim 9, wherein the carrier substrate is wafer-sized, and wherein depositing the upper redistribution layer comprises depositing a wafer-sized upper redistribution layer.

14. The method of claim 9, further comprising:
bonding a back side of a third memory die to the carrier substrate;
bonding a back side of at least one fourth memory die to an active surface of the third memory die so as to leave a lateral portion of the third memory die uncovered by the at least one fourth memory die; and
depositing metal pillars on the lateral portion of third memory die, wherein encapsulating the first memory die and the at least one second memory die with the first mold compound further comprises encapsulating the third memory die and the at least one fourth memory die with the first mold compound.

15. An integrated circuit package comprising:
an upper redistribution layer;
a first stack of memory dies;
a first plurality of vertical wire bonds coupled between the first stack of memory dies and the upper redistribution layer;
a lower redistribution layer;
a logic die;
a plurality of interconnects coupled between the logic die and the lower redistribution layer;
a second stack of memory dies; and
a third plurality of vertical wire bonds coupled between the second stack and the lower redistribution layer.

16. The integrated circuit package of claim 15, further comprising:
a plurality of through-mold vias coupled between the upper redistribution layer and the lower redistribution layer.

17. The integrated circuit package of claim 15, further comprising:
a third stack of memory dies; and
a third plurality of vertical wire bonds coupled between the third stack of memory dies and the upper redistribution layer.

18. The integrated circuit package of claim 15, wherein the first stack of memory dies comprises a stack of dynamic random-access memory dies, and wherein each successive one of the dynamic random-access memory dies in the first stack is displaced laterally in a first direction from a preceding one of the dynamic random-access memory dies in the first stack.

19. The integrated circuit package of claim 15, wherein the plurality of interconnects comprises a plurality of metal pillars.

20. The integrated circuit package of claim 15, wherein the plurality of interconnects comprises a plurality of micro bumps.
